(19) United States
(12) Patent Application Publication
(10) Pub. No.: US 2023/0068847 A1
(43) Pub. Date: Mar. 2, 2023

(54) SYSTEMS AND METHODS FOR DETECTING BOTH VEHICLE BATTERY CONNECTION AND VEHICLE BATTERY POLARITY USING A SINGLE SENSOR CIRCUIT

(71) Applicant: Deltran Operations USA, Inc., Deland, FL (US)

(72) Inventor: Edward Brumley, Deland, FL (US)

(21) Appl. No.: 17/890,474

(22) Filed: Aug. 18, 2022

Related U.S. Application Data
(60) Provisional application No. 63/240,221, filed on Sep. 2, 2021.

(51) Int. Cl. G01R 31/3835

(52) U.S. Cl. CPC G01R 31/3835

(57) ABSTRACT

System and methods for operating a portable device. The methods comprise: detecting, by a voltage monitor circuit, an output voltage of an external battery; providing a single output signal from the voltage monitor circuit to a function selector of the portable device, where the single output signal has a variable voltage value; and using, by the function selector, a current voltage level of the single output signal to determine whether the external battery is connected to the portable device and determine whether a reverse polarity connection exists between the external battery and the portable device.

### CROSS-REFERENCE TO RELATED APPLICATIONS

The present application claims priority to and the benefit of U.S. Provisional Patent Application Ser. No. 63/240,221 which was filed on Sep. 2, 2021. The content of this application is incorporated herein by reference in its entirety.

### STATEMENT OF THE TECHNICAL FIELD

The present disclosure relates generally to batteries. More particularly, the present disclosure relates to implementing systems and methods for detecting both vehicle battery connection and vehicle battery polarity using a single sensor.

### BACKGROUND

### Description of the Related Art

Vehicles typically have internal batteries. A portable device can be used to jump start the vehicle under conditions where the internal battery is partially discharged.

### SUMMARY

The presents document concerns implementing systems and methods for operating a portable device. The portable device may be configured to jump start a vehicle and/or charge an external battery. The methods comprise: detecting, by a voltage monitor circuit, an output voltage of an external battery; providing a single output signal from the voltage monitor circuit to a function selector of the portable device (where the single output signal has a variable voltage value); and using, by the function selector, a current voltage level of the single output signal to determine whether the external battery is connected to the portable device and determine whether a reverse polarity connection exists between the external battery and the portable device. The function selector may also cause a switch to be closed for electrically connecting the external battery to a power supply circuit internal to the portable device when the external battery is connected to the portable device and a reverse polarity connection does not exist between the external battery and the portable device. The switch may be maintained in an open position when the external battery is connected to the portable device and a reverse polarity connection exists between the external battery and the portable device.

The function selector may optionally use the current voltage level of the single output signal to compute a battery voltage for the external battery. A determination may be made that a correct polarity connection exists between the external battery and the portable device when the variable voltage value of the single output signal is between Vmin Volts and 0.75 Vcc Volts, is between Vmin Volts and Vcc Volts, or is between 0 Volts and Vcc Volts. Vcc is a power supply voltage of the portable device. A determination may be made that a reverse polarity connection exists between the external battery and the portable device when: the variable voltage value of the single output signal is zero volts or is between 0.9 to 1.0 Vcc Volts; or the variable voltage value of the single output signal is equal to a power supply voltage of the portable device.

A determination may be made that the external battery is connected to the portable device when: one of two field effect transistors is in an on state; or an opto-isolator is in an active state. A determination may be made that the external battery is not connected to the portable device when: both of said two field effect transistors are in an off state; or the opto-isolator is in an inactive state.

The present document also concerns a portable device. The portable device comprises: a voltage monitor circuit that detects an output voltage of an external battery when the external battery is electrically connected to the portable device; and a function selector circuit that is electrically connected to the voltage monitor circuit. The function selector is configured to: receive a single output signal from the voltage monitor circuit when the output voltage of the external battery is detected; and use a current voltage level of the single output signal to (i) determine whether the external battery is connected to the portable device and (ii) determine whether a reverse polarity connection exists between the external battery and the portable device. The single output signal has a variable voltage value.

The current voltage level of the single output signal may be used by the function selector circuit to compute a battery voltage for the external battery. The function selector may perform operations to cause an electrical connection to be established between the external battery to a power supply circuit internal to the portable device when the external battery is connected to the portable device and a reverse polarity connection does not exist between the external battery and the portable device. The switch may be in an open position when the external battery is connected to the portable device and a reverse polarity connection exists between the external battery and the portable device.

A determination may be made by the function selector that a correct polarity connection exists between the external battery and the portable device when the variable voltage value of the single output signal is between Vmin Volts and 0.75 Vcc Volts, is between Vmin Volts and Vcc Volts, or is between 0 Volts and Vcc Volts. Vcc is a power supply voltage of the portable device. The function selected may determine that a reverse polarity connection exists between the external battery and the portable device when: the variable voltage value of the single output signal is zero volts or is between 0.9 to 1.0 Vcc Volts; or the variable voltage value of the single output signal is equal to a power supply voltage of the portable device.

In some scenarios, the voltage monitor circuit comprises two field effect transistors that are connected between input lines. The function selector may determine that the external battery is connected to the portable device when one of two field effect transistors of the voltage monitor circuit is in an on state. The function selector may determine that the external battery is not connected to the portable device when both field effect transistors of the voltage monitor circuit are in an off state.

In those or other scenarios, the voltage monitor circuit comprises an opto-isolator connected between input lines. The function selector may determine that the external battery is connected to the portable device when the opto-isolator of the voltage monitor circuit is in an active state. The function selector may determine that the external battery is not connected to the portable device when the opto-isolator of the voltage monitor circuit is in an inactive state.

### BRIEF DESCRIPTION OF THE DRAWINGS

The present solution will be described with reference to the following drawing figures, in which like numerals represent like items throughout the figures.

FIG. 1 provides an illustration of a system.

FIG. 2 provides an illustration of a voltage and reverse polarity monitoring circuit.

FIG. 3 provides an illustration of another voltage and reverse polarity monitoring circuit.

FIG. 4 provides an illustration of another voltage and reverse polarity monitoring circuit.

FIG. 5 provides an illustration of another voltage and reverse polarity monitoring circuit.

FIG. 6 provides a flow diagram of an illustrative method for operating a portable device.

FIG. 7 is an illustration of a computing device.

### DETAILED DESCRIPTION

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to.” Definitions for additional terms that are relevant to this document are included at the end of this Detailed Description.

The solution described herein facilitates three functions in one portable device that can be used with vehicles (for example, cars, trucks, motorcycles, unmanned vehicles, etc.). The three functions include (1) voltage monitoring, (2) charging of the vehicle battery, and (3) jump starting a vehicle under conditions where the vehicle battery is partially discharged.

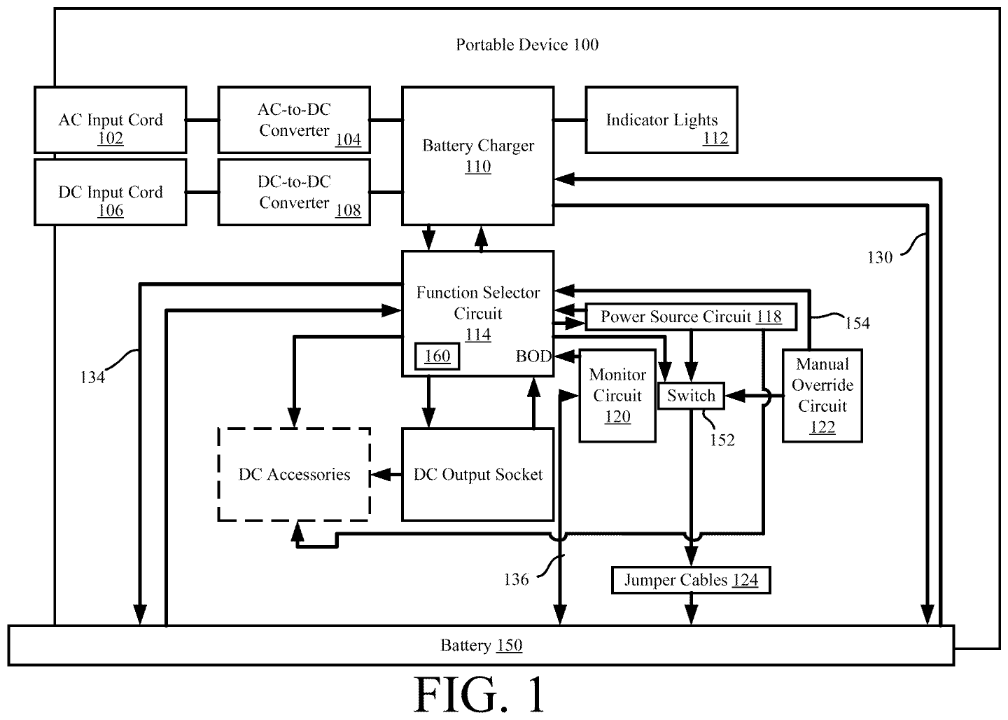

An illustration of a system is provided in FIG. 1 that implements the present solution. The system comprises a portable device 100 that can be coupled to and decoupled from an external battery 150 of a vehicle (for example, cars, trucks, motorcycles, unmanned vehicles, etc.). Vehicle batteries are well known. The vehicle is not shown in FIG. 1 simply for ease of illustration.

The portable device 100 comprises an AC input cord 102 for electrically connecting an external AC power source (for example, an AC mains) to the portable device 100. A received AC signal is passed to an AC-to-DC converter 104 prior to being provided to a battery charger 110. A DC input cord 106 is also provided for electrically connecting an external DC power source (for example, a cigarette lighter) to the portable device 100. A received DC signal is passed to a DC-to-DC converter 108 prior to being provided to a battery charger 110. The battery charger 110 is configured to charge an external battery 150 of the vehicle using power received from the external power source(s), as shown by connection lines 130. Indicator lights 112 provide a visual indication of the operational state of the battery charger 110 (for example, in a charging mode or a standby mode).

The external battery 150 may also be charged by a power source circuit 118 via jumper cables 124 to facilitate a jump start of the vehicle. Power source circuit 118 is internal to the system 100.

When the vehicle battery 150 is excessively discharged, performing a jump start operation on the vehicle can potentially result in damage to the battery. For this reason, the solution disclosed herein includes a voltage monitor circuit 120 to facilitate an evaluation of the connection, polarity and state of the vehicle battery 150. If certain conditions are met, then the jump-starting function of the system can be used to immediately facilitate jump starting the vehicle. Such jump-starting operations can be performed using the power supply circuit 118. The external battery 150 may be charged by the power supply circuit 118 via jumper cables 124.

A function selector circuit 114 monitors a voltage signal generated by the voltage monitor circuit 120. The function selector circuit 114 can include, but is not limited to, a computing device. The function selector circuit 114 is configured to make determinations based on the voltage level of the voltage signal. For example, the function selector circuit 114 performs operations to (i) determine whether the external battery 150 is connected to the portable device 100, and (ii) determine whether a reverse polarity connection exists between the external battery 150 and the portable device 100. Results of these determinations (i) and (ii) are then used to determine whether the external battery 150 will be damaged if jump started using the power supply circuit 118.

If so, then the function selector circuit 114 performs operations to (i) notify the user of the portable device 100 that the battery could be damaged if jump started and (ii) conclude that the switch 152 should remain in its current open position or state so that the vehicle will not be jump started. A user-operated manual override switch 122 may be provided to allow the user to cause a switch 152 to change positions or otherwise be operated for jump starting of the battery 150—even at the risk of damaging the battery. For example, the switch 152 can be transitioned from an open position to a closed position via the user-operated manual override switch 122. The manual override circuit 122 may also notify the function selector circuit 114 of the user override input via connection line 154 so that a voltage signal is not provided to the external battery 150 via connection line 134 while the power source circuit 118 is being used to charge the external battery 150. The present solution is not limited to the particulars of this example. The user-operated manual override switch 122 may include, but is not limited to, a depressible physical button or a virtual button on a touch screen.

If not, then the function selector circuit 114 performs operations to cause a voltage signal to be provided from the power supply circuit 118 to the external battery 150 via jumper cables 124. These operations can involve causing the switch 152 to transition from its open position/state to its closed position/state for providing an electrical connection between the power source circuit 118 and the jumper cables 124 which are connected to the vehicle battery 150. The power supply circuit 118 may, for example, provide a twelve volt power source for jump starting a twelve volt external battery. In this case, Vcc would be twelve volts. The present solution is not limited to this particular voltage. The value Vcc of can be selected in accordance with a given application. This circuit is valid for any application using a connected external battery.

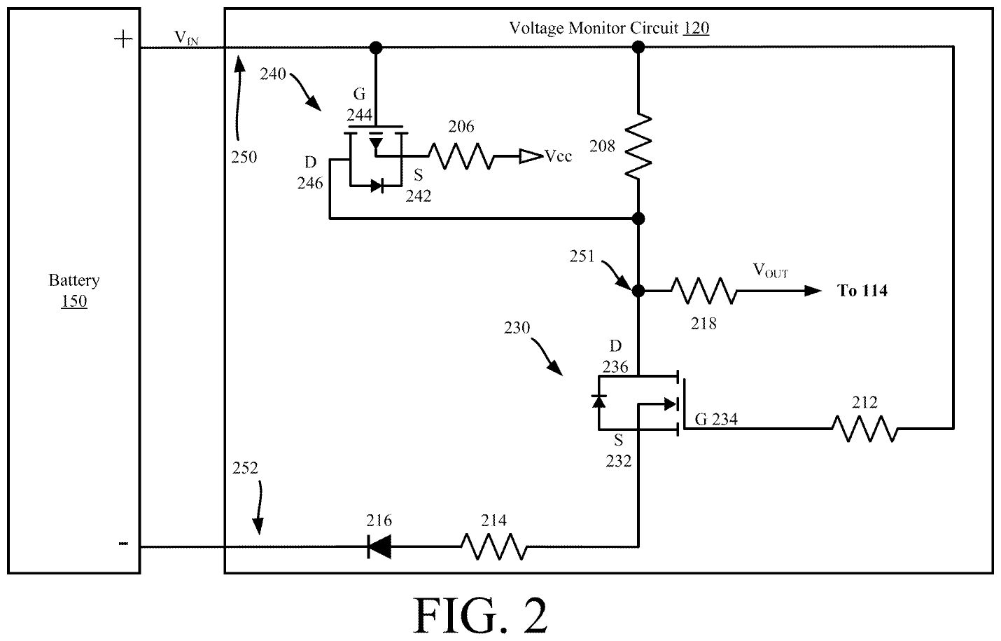

An illustration is provided in FIG. 2 of a voltage and reverse polarity monitoring circuit 120 to facilitate the above-mentioned determinations (i) and (ii). A shown in FIG. 2, the voltage monitor circuit 120 provides a single output signal V_{OUT} to the function selector circuit 114. The voltage monitor circuit 120 comprises switches 230, 240, resistors 206, 208, 212, 214, 218 and a diode 216. Diode 216 provides reverse polarity protection to the voltage monitor circuit 120 by preventing current from flowing from the negative terminal connection to the external battery 150 to the voltage monitor circuit 120 when a reverse polarity connection exists between the external battery 150 and the portable device 100. Resistors 212 and 218 are optional components and may be replaced with zero ohm resistors.

Switch 230 comprises an enhancement mode Metal Oxide Semiconductor FETs (“MOSFETs”) of an N-channel type, and switch 240 comprises a MOSFET of a P-channel type. Each MOSFET has three (3) terminals respectively defined as a source, gate and drain. With regard to the first MOSFET 230, the source, gate and drain terminals are respectively identified with reference numbers 232, 234, 236. The source, gate and drain terminals of the second MOSFET 240 are respectively identified with reference numbers 242, 244, 246. An electrical path is provided from the source to the drain of each MOSFET 230, 240. This path is generally referred to herein as the source-drain path.

The MOSFETs 230, 240 are connected in series between input lines 250, 252. Gate 244 of MOSFET 240 is connected to input line 250. Source 242 of MOSFET 240 is connected to Vcc via resistor 206. Drain 246 of MOSFET 240 is connected to drain 236 of MOSFET 230. Source 232 of MOSFET 230 is connected to input line 252. Gate 234 of MOSFET 230 is connected to input line 250 via resistor 212.

MOSFET 240 is in an “off” state when MOSFET 230 is in its “on state”. Similarly, MOSFET 230 is in its “off” state when MOSFET 240 is in its “on” state. MOSFET 230 is in its “on” state when a correct polarity connection exists between the external battery 150 and the portable device 100, and is in its “off” state when a reverse polarity connection exists between external battery 150 and the portable device 100. In contrast, MOSFET 240 is in its “on” state when the reverse polarity connection exists between external battery 150 and the portable device 100, and is in its “off” state when the correct polarity connection exists between external battery 150 and the portable device 100.

MOSFET 230 is transitioned to its “on” state by applying a first positive voltage (for example, 1-60 Volts) to its drain and a second positive voltage (for example, 1-60 Volts) to its gate while maintaining a lower potential on the source. Current flows through the drain-source channel when the first and second positive voltages are applied to the MOSFET 230. When this occurs, resistors 208 and 214 act as a voltage divider circuit. Resisters 208 and 214 are connected in series such that a voltage tap 251 is provided at a connection point between the voltage monitor circuit 120 and the function selector circuit 114 of the portable device 100. The voltage tap 251 provides a reduced voltage output relative to the input voltage applied to the voltage monitor circuit 120 by the external battery 150. The voltage tap 251 can provide an output voltage V_{OUT} that is reduced by 10-90% relative to the input voltage V_{IN} such that the output voltage V_{OUT} falls between Vmin Volts and 0.75 Vcc Volts. The function selector circuit 114 determines that a correct polarity connection exists between external battery 150 and the portable device 100 when V_{OUT} has a value of Vmin Volts-0.75 Vcc Volts. Vmin is the voltage in which the potential between the MOSFET source and gate will overcome the specifications of the MOSFET and cause it to function like a switch.

The function selector circuit 114 may also compute the battery voltage of the external battery 150 using the value of V_{OUT}. For example, the function selector circuit 114 uses an ADC conversion to convert the analog voltage V_{OUT} to a digital voltage representing the battery voltage of the external battery 150. The present solution is not limited in this regard.

MOSFET 240 is transitioned to its “on” state when a potential on the gate 244 is sufficiently lower than the potential on the source 242. Current flows through source-drain channel when this occurs. In effect, V_{OUT} has a value between 0.9-1.0 Vcc Volts. The function selector circuit 114 determines that the circuit is in standby. This state encompasses reverse polarity, no battery connector or connection, or a battery that has a voltage too low to charge safely. This connection exists between external battery 150 and the portable device 100 when V_{OUT} has a value of 0.9-1.0 Vcc Volts.

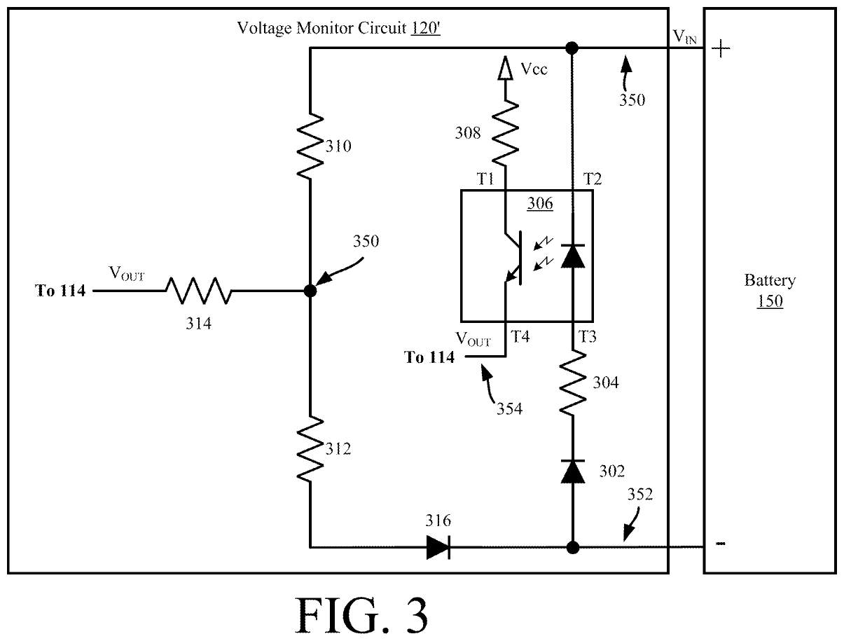

An illustration is provided in FIG. 3 of another voltage and reverse polarity monitoring circuit 120′ to facilitate determinations (i) and (ii) mentioned above. A shown in FIG. 3, the voltage monitor circuit 120′ provides a single output signal V_{OUT} to the function selector circuit 114. The signal V_{OUT} has a variable voltage value. The voltage monitor circuit 120′ comprises an opto-isolator 306, resistors 304, 308, 310, 312, 314, and diodes 302, 316. Diode 316 provides reverse polarity protection for the voltage monitor circuit 120′ by preventing current from flowing from the negative terminal of the external battery 150 to the voltage monitor circuit 120′ when a reverse polarity connection exists between the external battery 150 and the portable device 100. Resistor 314 is optional and may be replaced with a zero ohm resistor.

The opto-isolator 306 has four terminals T1, T2, T3, T4. Terminal T1 is connected to Vcc via resistor 308. Terminal T2 is connected to an input line 350. Terminal T3 is connected to input line 352 via resistor 304 and diode 302. Terminal T4 is connected to an output line 354. The opto-isolator 306 is configured to transition between an active state and an inactive state (and vice versa) based on whether the external battery 150 is or is not correctly connected to the voltage monitor circuit 120′.

When a correct connection exists between the external battery 150 and the portable device 100, the opto-isolator 306 is in an inactive state. As such, the input voltage V_{IN} is provided from the external battery 150 to a voltage divider circuit. The voltage divider circuit comprises resistors 310 and 312. Resistors 310 and 312 are connected in series such that a voltage tap 350 is provided at a connection point between the voltage monitor circuit 120′ and the function selector circuit 114 of the portable device 100. The voltage tap 350 provides a reduced voltage output relative to the input voltage V_{IN}. The voltage tap 350 can provide an output voltage V_{OUT} that is reduced by 10-90% relative to the input voltage V_{IN} such that the output voltage V_{OUT} falls between 0 Volts and 0.75 Vcc. The function selector circuit 114 determines that a correct polarity connection exists between external battery 150 and the portable device 100 when V_{OUT} has a value of 0 Volts-0.75 Vcc Volts. The function selector circuit 114 may also compute the battery voltage of the external battery 150 using the value of V_{OUT} (for example, using an ADC conversion).

When an incorrect or reverse polarity connection exists between the external battery 150 and the portable device 100, the opto-isolator 306 is in an active state. As such, the output voltage V_{OUT} is pulled to Vcc and provided to the function selector circuit 114. The function selector circuit 114 determines that a reverse polarity connection exists between external battery 150 and the portable device 100 when V_{OUT} has a value equal to Vcc.

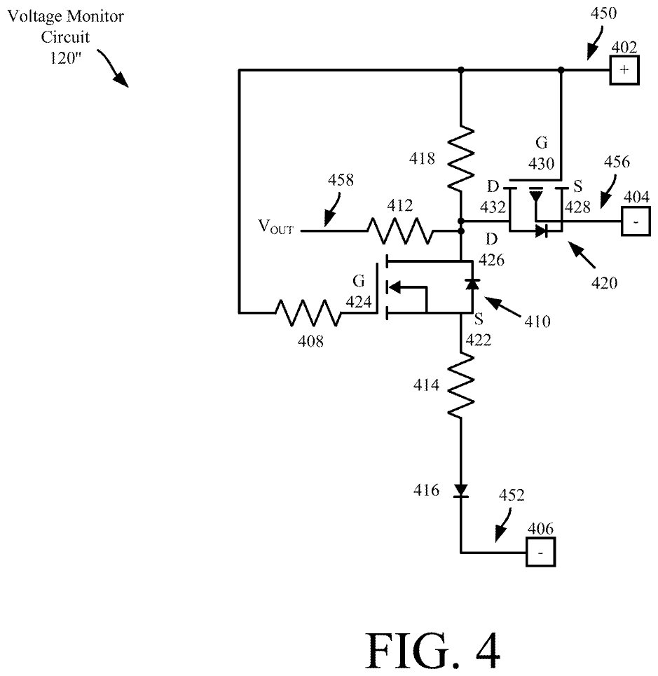

An illustration is provided in FIG. 4 of another voltage and reverse polarity monitoring circuit 120″ to facilitate determinations (i) and (ii) mentioned above. This voltage monitor circuit is similar to the circuit of FIG. 2 with the battery orientation detect by pulling an Analog Digital Converter (ADC) 160 of the function selector 114 low instead of high. This circuit is useful when a more dynamic range is needed for the ADC 160 of the function selector 114. A battery voltage is detected by the system when the voltage V_{OUT} on output line 458 is within the range of Vmin Volts to Vcc Volts. A battery reverse orientation is detected by system when the voltage V_{OUT} on output line 458 is 0 Volts.

Terminals 402 and 406 are the terminals to which the external battery 150 can be connected. Resistors 418 and 414 provide a voltage divider set so the maximum battery voltage produces a divided voltage of Vcc. Diode 416 is a blocking diode configured to block voltage when a reverse connection is applied to protect the function selector circuit 114 (for example, a microprocessor).

Switches 410 and 420 are connected between input lines 450, 452. Switches 410 and 420 may comprise MOSFETs. Switch 410 comprises an enhancement mode Metal Oxide Semiconductor FETs (“MOSFETs”) of an N-channel type, and switch 420 comprises a MOSFET of a P-channel type. Each MOSFET has three (3) terminals respectively defined as a source, gate and drain. With regard to the first MOSFET 410, the source, gate and drain terminals are respectively identified with reference numbers 422, 424, 426. The source, gate and drain terminals of the second MOSFET 420 are respectively identified with reference numbers 428, 430, 432. An electrical path is provided from the source to the drain of each MOSFET 410, 420. This path is generally referred to herein as the source-drain path.

The MOSFETs 410, 420 are connected between input lines 450, 452. Gate 430 of MOSFET 420 is connected to input line 450. Source 428 of MOSFET 420 is connected to input line 456. Drain 432 of MOSFET 420 is connected to drain 426 of MOSFET 410. Source 422 of MOSFET 410 is connected to input line 452 via resistor 414 and diode 416. Gate 424 of MOSFET 410 is connected to input line 450 via resistor 408.

When a battery is connected in the correct orientation to the portable device 100, switch 410 transitions to a closed state and switch 420 transitions to an open state. In this configuration, a voltage V_{OUT} on output line 458 will simply be the output of the voltage divider 418/414. If a battery is connected in a reverse orientation to the portable device 100, switch 410 transitions to an open state and switch 420 transitions to a closed state. In this configuration, the voltage V_{OUT} on line 458 is zero volts.

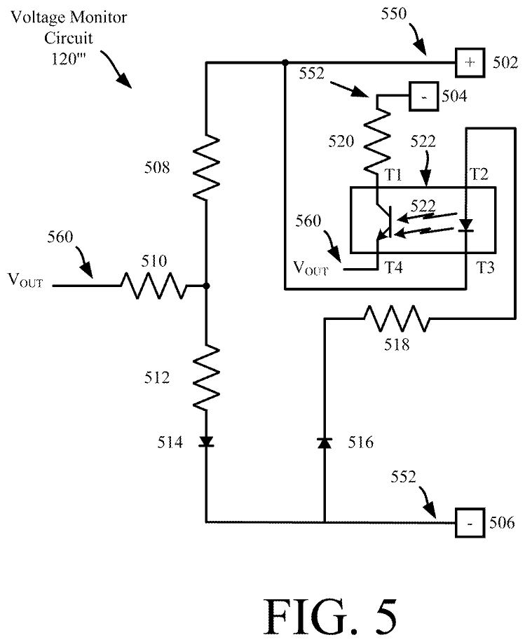

An illustration is provided in FIG. 5 of yet another voltage and reverse polarity monitor circuit 120′″ to facilitate determinations (i) and (ii) mentioned above. Voltage monitor circuit 120′″ comprises an opto-isolator 522, resistors 508, 510, 512, 518, 520, and diodes 514, 516. Resistors 510, 518, 520 are optional and may be replaced with zero ohm resistors.

Voltage monitor circuit 120′″ is similar to the circuit of FIG. 3 with the battery's orientation being detected using an opto-isolator instead of a MOSFET. The voltage monitor circuit 120′″ is also similar to the circuit in FIG. 2 with the battery's orientation being detected by pulling the ADC 160 of the function selector 114 low instead of high. This circuit is useful when a more dynamic range is needed for the ADC 160 of the function selector 114. The battery's voltage is detected when a voltage V_{OUT} on output line 560 is within the range 0 Volts to Vcc Volts. The battery's reverse orientation is detected when the voltage V_{OUT} on output line 560 is zero volts.

Terminals 502 and 506 are the terminal to which the external battery 150 can be connected. Resistors 508 and 512 are configured to provide a voltage divider set so the maximum battery voltage will give a divided voltage of 0.75 Vcc Volts. Diode 514 is a blocking diode configured to block a voltage when a reverse connection is applied. This prevents damage to the function selector circuit 114 (for example, a microprocessor) and any potential issues with voltage measurements at the BOD pin of the function selector circuit 114 (for example, a microprocessor).

Opto-isolator 522 has four terminals T1, T2, T3, T4. Terminal T1 is connected to input line 552 via resistor 520. Terminal T2 is connected to input line 552 via resistor 518 and diode 516. Terminal T3 is connected to input line 550. Terminal T4 is connected to output line 560.

Opto-isolator 522 is configured to remain inactive when the battery 150 is connected in the correct orientation. When the battery 150 is connected in the correct orientation, the voltage V_{OUT} on output line 560 is simply the output of the voltage divider 508/512. If the battery 150 is connected in a reverse orientation, then the opto-isolator 522 pulls the voltage of output line 560 to zero volts.

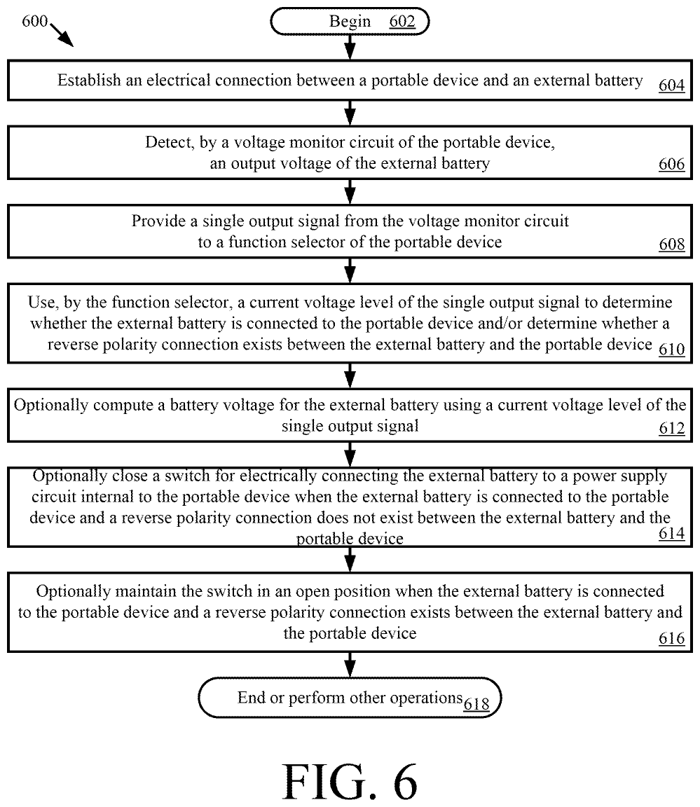

Referring now to FIG. 6, there is provided a flow diagram of an illustrative method 600 for operating a portable device (for example, portable device 100 of FIG. 1). Method 600 begins with 602 and continues with 604 where an electrical connection is established between the portable device and an external battery (for example, battery 150 of FIG. 1). The electrical connection can be established, for example, using jumper cables (for example, jumper cables 124 of FIG. 1) and/or other cable(s) (for cable(s) 136 of FIG. 1). The jumper cables are provided to facilitate the selective coupling and decoupling of a power source circuit (for example, power source circuit 118 of FIG. 1) to/from the battery as will be discussed below. The other cable(s) are provided to connect the battery to a voltage monitor circuit (for example, voltage monitor circuit 120 of FIG. 1). Both the power source circuit and the voltage monitor circuit are internal to the portable device.

Next in 606, the voltage monitor circuit performs operations to detect an output voltage of the external battery. This voltage can be detected by measuring a voltage on a cable or line connecting the voltage monitor circuit and external battery to each other. A single output signal is provided from the voltage monitor circuit to a function selector circuit (for example, function selector circuit 114 of FIG. 1) of the portable device, as shown by 608. The single output signal has a variable voltage value.

In 610, the function selector circuit uses a current voltage level of the single output signal to determine: whether the external battery is connected to the portable device; and/or whether a reverse polarity connection exists between the external battery and the portable device.

A determination may be made that a correct polarity connection exists between the external battery and the portable device when the variable voltage value of the single output signal is between Vmin Volts and 0.75 Vcc Volts, is between Vmin Volts and Vcc Volts, or is between 0 Volts and Vcc Volts. Vcc is a power supply voltage of the portable device. In some scenarios, Vcc is between five volts and twenty-five voltages. For example, Vcc is twelve volts when the external battery is a twelve volt battery. The present solution is not limited to the particulars of this example. A determination may be made that a reverse polarity connection exists between the external battery and the portable device when: the variable voltage value of the single output signal is zero volts or is between 0.9 to 1.0 Vcc Volts; or the variable voltage value of the single output signal is equal to a power supply voltage of the portable device.

A determination may be made that the external battery is connected to the portable device when: one of two field effect transistors is in an on state; or an opto-isolator is in an active state. A determination may be made that the external battery is not connected to the portable device when: both of said two field effect transistors are in an off state; or an opto-isolator is in an inactive state.

The function selector circuit may optionally perform operations to compute a battery voltage for the external battery using a current voltage level of the single output signal, as shown by 612. In 614, a switch is optionally closed to electrically connect the external battery to a power supply circuit (for example, power supply circuit 118 of FIG. 1) internal to the portable device. This may occur when the external battery is connected to the portable device and a reverse polarity connection does not exist between the external battery and the portable device. As shown by 616, the switch is maintained in its open position when the external battery is connected to the portable device and a reverse polarity connection exists between the external battery and the portable device. Upon completing 612, 614 or 616, 618 is performed where method 600 ends or other operations are performed (for example, return to 604).

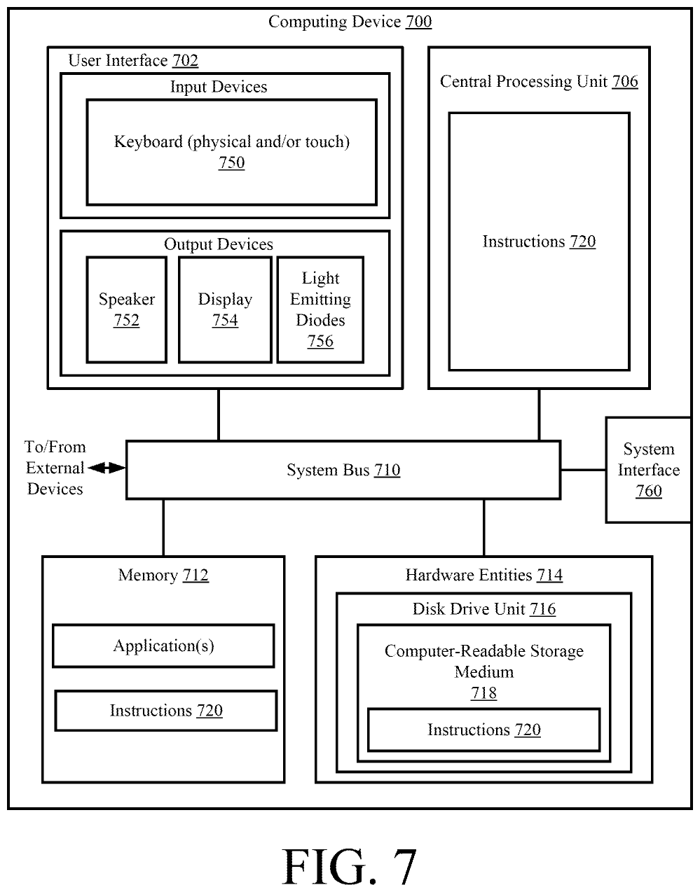

Referring now to FIG. 7, there is shown an illustrative architecture for a computing device 700. The function selector circuit 114 of FIG. 1 may be the same as or similar to computing device 700. As such, the discussion of computing device 700 is sufficient for understanding the component 114 of FIG. 1.

Computing device 700 may include more or less components than those shown in FIG. 7. However, the components shown are sufficient to disclose an illustrative solution implementing the present solution. The hardware architecture of FIG. 7 represents one implementation of a representative computing device configured to operate a portable device, as described herein. As such, the computing device 700 of FIG. 7 implements at least a portion of the method(s) described herein.

Some or all components of the computing device 700 can be implemented as hardware, software and/or a combination of hardware and software. The hardware includes, but is not limited to, one or more electronic circuits. The electronic circuits can include, but are not limited to, passive components (e.g., resistors and capacitors) and/or active components (e.g., amplifiers and/or microprocessors). The passive and/or active components can be adapted to, arranged to and/or programmed to perform one or more of the methodologies, procedures, or functions described herein.

As shown in FIG. 7, the computing device 700 comprises a user interface 702, a Central Processing Unit (CPU) 706, a system bus 710, a memory 712 connected to and accessible by other portions of computing device 700 through system bus 710, a system interface 760, and hardware entities 714 connected to system bus 710. The user interface can include input devices and output devices, which facilitate user-software interactions for controlling operations of the computing device 700. The input devices include, but are not limited to, buttons, a physical keyboard 750 and/or a touch keyboard 750. The input devices can be connected to the computing device 700 via a wired or wireless connection (e.g., a Bluetooth® connection). The output devices include, but are not limited to, a speaker 752, a display 754, and/or light emitting diodes 756. Indicator lights 112 of FIG. 1 can be the same as, similar to and/or comprise light emitting diodes 756. System interface 760 is configured to facilitate wired or wireless communications to and from external devices (e.g., network nodes such as access points, etc.).

At least some of the hardware entities 714 perform actions involving access to and use of memory 712, which can be a Random Access Memory (RAM), a disk drive, flash memory, a Compact Disc Read Only Memory (CD-ROM) and/or another hardware device that is capable of storing instructions and data. Hardware entities 714 can include a disk drive unit 716 comprising a computer-readable storage medium 718 on which is stored one or more sets of instructions 720 (e.g., software code) configured to implement one or more of the methodologies, procedures, or functions described herein. The instructions 720 can also reside, completely or at least partially, within the memory 712 and/or within the CPU 706 during execution thereof by the computing device 700. The memory 712 and the CPU 706 also can constitute machine-readable media. The term “machine-readable media”, as used here, refers to a single medium or multiple media (e.g., a centralized or distributed database, and/or associated caches and servers) that store the one or more sets of instructions 720. The term “machine-readable media”, as used here, also refers to any medium that is capable of storing, encoding or carrying a set of instructions 720 for execution by the computing device 700 and that cause the computing device 700 to perform any one or more of the methodologies of the present disclosure.

Although the present solution has been illustrated and described with respect to one or more implementations, equivalent alterations and modifications will occur to others skilled in the art upon the reading and understanding of this specification and the annexed drawings. In addition, while a particular feature of the present solution may have been disclosed with respect to only one of several implementations, such feature may be combined with one or more other features of the other implementations as may be desired and advantageous for any given or particular application. Thus, the breadth and scope of the present solution should not be limited by any of the above described embodiments. Rather, the scope of the present solution should be defined in accordance with the following claims and their equivalents.

What is claimed is:

1. A method for operating a portable device, comprising:
detecting, by a voltage monitor circuit, an output voltage of an external battery;
providing a single output signal from the voltage monitor circuit to a function selector of the portable device, where the single output signal has a variable voltage value; and
using, by the function selector, a current voltage level of the single output signal to determine whether the external battery is connected to the portable device and determine whether a reverse polarity connection exists between the external battery and the portable device.

2. The method according to claim 1, further comprising performing operations, by the function selector, to close a switch for electrically connecting the external battery to a power supply circuit internal to the portable device when the external battery is connected to the portable device and a reverse polarity connection does not exist between the external battery and the portable device.

3. The method according to claim 1, further comprising maintaining a switch of the portable device in an open position when the external battery is connected to the portable device and a reverse polarity connection exists between the external battery and the portable device.

4. The method according to claim 1, further comprising computing a battery voltage for the external battery using a current voltage level of the single output signal.

5. The method according to claim 1, wherein a determination is made that a correct polarity connection exists between the external battery and the portable device when the variable voltage value of the single output signal is between Vmin Volts and 0.75 Vcc Volts, is between Vmin Volts and Vcc Volts, or is between 0 Volts and Vcc Volts, where Vcc is a power supply voltage of the portable device.

6. The method according to claim 1, wherein a determination is made that a reverse polarity connection exists between the external battery and the portable device when the variable voltage value of the single output signal is zero volts or is between 0.9 to 1.0 Vcc Volts, where Vcc is a power supply voltage of the portable device.

7. The method according to claim 1, wherein a determination is made that a reverse polarity connection exists between the external battery and the portable device when the variable voltage value of the single output signal is equal to a power supply voltage of the portable device.

8. The method according to claim 1, wherein a determination is made that the external battery is connected to the portable device when one of two field effect transistors is in an on state.

9. The method according to claim 1, wherein a determination is made that the external battery is not connected to the portable device when both of said two field effect transistors are in an off state.

10. The method according to claim 1, wherein a determination is made that the external battery is connected to the portable device when an opto-isolator is in an active state.

11. The method according to claim 1, wherein a determination is made that the external battery is not connected to the portable device when an opto-isolator is in an inactive state.

12. A portable device, comprising:
a voltage monitor circuit that detects an output voltage of an external battery when the external battery is electrically connected to the portable device; and
a function selector circuit that is electrically connected to the voltage monitor circuit, receives a single output signal from the voltage monitor circuit when the output voltage of the external battery is detected, and uses a current voltage level of the single output signal to determine whether the external battery is connected to the portable device and determine whether a reverse polarity connection exists between the external battery and the portable device;
wherein the single output signal has a variable voltage value.

13. The portable device according to claim 12, wherein the function selector performs operations to cause an electrical connection to be established between the external battery to a power supply circuit internal to the portable device when the external battery is connected to the portable device and a reverse polarity connection does not exist between the external battery and the portable device.

14. The portable device according to claim 12, further comprising a switch that is in an open position when the external battery is connected to the portable device and a reverse polarity connection exists between the external battery and the portable device.

15. The portable device according to claim 12, wherein the current voltage level of the single output signal is used by the function selector circuit to compute a battery voltage for the external battery.

16. The portable device according to claim 12, wherein a determination is made that a correct polarity connection exists between the external battery and the portable device when the variable voltage value of the single output signal is between Vmin Volts and 0.75 Vcc Volts, is between Vmin Volts and Vcc Volts, or is between 0 Volts and Vcc Volts, where Vcc is a power supply voltage of the portable device.

17. The portable device according to claim 12, wherein a determination is made that a reverse polarity connection exists between the external battery and the portable device when the variable voltage value of the single output signal is zero volts or is between 0.9 to 1.0 Vcc Volts, where Vcc is a power supply voltage of the portable device.

18. The portable device according to claim 12, wherein a determination is made that a reverse polarity connection exists between the external battery and the portable device when the variable voltage value of the single output signal is equal to a power supply voltage of the portable device.

19. The portable device according to claim 12, wherein the voltage monitor circuit comprises two field effect transistors that are connected between input lines.

20. The portable device according to claim 19, wherein a determination is made that the external battery is connected to the portable device when one of two field effect transistors of the voltage monitor circuit is in an on state.

21. The portable device according to claim 19, wherein a determination is made that the external battery is not connected to the portable device when both of said two field effect transistors of the voltage monitor circuit are in an off state.

22. The portable device according to claim 12, wherein the voltage monitor circuit comprises an opto-isolator connected between input lines.

23. The portable device according to claim 22, wherein a determination is made that the external battery is connected to the portable device when the opto-isolator of the voltage monitor circuit is in an active state.

24. The portable device according to claim 22, wherein a determination is made that the external battery is not connected to the portable device when the opto-isolator of the voltage monitor circuit is in an inactive state.
